(19) United States
(12) Patent Application Publication
(10) Pub. No.: US 2026/0107468 A1
(43) Pub. Date: Apr. 16, 2026

(54) SEMICONDUCTOR DEVICE AND DATA STORAGE SYSTEM INCLUDING THE SAME

(71) Applicant: Samsung Electronics Co., Ltd., Suwon-si (KR)

(72) Inventors: Seungjae BAIK, Suwon-si (KR); Sungbok LEE, Suwon-si (KR); Kibong MOON, Suwon-si (KR)

(73) Assignee: Samsung Electronics Co., Ltd., Suwon-si (KR)

(21) Appl. No.: 19/199,845

(22) Filed: May 6, 2025

(30) Foreign Application Priority Data
Oct. 11, 2024 (KR) 10-2024-0138792

(51) Int. Cl. H10B 43/35; H01L 23/00; H01L 25/00; H01L 25/065; H01L 25/18; H10B 43/27; H10B 80/00

(52) U.S. Cl. CPC H10B 43/35; H10B 43/27; H10B 80/00; H10W 90/00; H10W 80/312; H10W 80/327; H10W 90/792

(57) ABSTRACT

Provided are a semiconductor device and a data storage system including the same. The semiconductor device may include a stack structure; a vertical structure penetrating the stack structure; and a contact plug on the vertical structure. The vertical structure may include a first semiconductor layer facing lower gate electrodes, intermediate gate electrodes, and upper gate electrodes of the stack structure; a second semiconductor layer at a higher level than the intermediate gate electrodes and facing at least one erase control gate electrode of the plurality of upper gate electrodes; and a conductive pad pattern spaced apart from the first semiconductor layer and in contact with the second semiconductor layer. The first semiconductor layer may include a first oxide semiconductor having N-type conductivity. The second semiconductor layer may includes at least one of a second oxide semiconductor, a Si semiconductor, a Ge semiconductor, or a SiGe semiconductor.

### CROSS-REFERENCE TO RELATED APPLICATION(S)

This application claims benefit of priority to Korean Patent Application No. 10-2024-0138792, filed on Oct. 11, 2024 in the Korean Intellectual Property Office, the disclosure of which is incorporated herein by reference in its entirety.

### BACKGROUND

Example embodiments of the present disclosure relate to a semiconductor device and/or a data system including the same.

A semiconductor device able to store high-capacity data may be required in a data storage system requiring data storage. Accordingly, a method for increasing data storage capacity of a semiconductor device has been researched. For example, as a method for increasing data storage capacity of a semiconductor device, a semiconductor device including memory cells disposed three-dimensionally, instead of memory cells disposed two-dimensionally, has been suggested.

### SUMMARY

An example embodiment of the present disclosure provides a semiconductor device which may improve erase efficiency of an erase operation.

An example embodiment of the present disclosure provides a data storage system including the semiconductor device.

According to an example embodiment of the present disclosure, a semiconductor device may include a peripheral structure including a peripheral circuit; and a memory structure vertically overlapping the peripheral structure. The memory structure may include a stack structure, a vertical structure, and a contact plug on the vertical structure. The stack structure may include interlayer insulating layers and conductive layers alternately stacked in a vertical direction. The vertical structure may be in a channel hole penetrating the stack structure. The conductive layers may include a plurality of lower gate electrodes, a plurality of intermediate gate electrodes on the plurality of lower gate electrodes, and a plurality of upper gate electrodes on the plurality of intermediate gate electrodes. The vertical structure may include a dielectric structure covering a sidewall of the channel hole and including a data storage layer, a first semiconductor layer covering an internal side surface of the dielectric structure, a conductive pad pattern connected to the contact plug, an insulating core pattern below the conductive pad pattern, and a second semiconductor layer between the first semiconductor layer and the conductive pad pattern. A first portion of the first semiconductor layer may be between the conductive pad pattern and the dielectric structure and a second portion of the of the first semiconductor layer may be between the insulating core pattern and the dielectric structure. A lower end of the second semiconductor layer may be at a higher level than the plurality of intermediate gate electrodes and at a lower level than a first upper erase control gate electrode among the plurality of upper gate electrodes. An upper end of the second semiconductor layer may be at a higher level than the first upper erase control gate electrode. The first semiconductor layer may include a first oxide semiconductor having N-type conductivity. The second semiconductor layer may include at least one of a second oxide semiconductor, a silicon (Si) semiconductor, a germanium (Ge) semiconductor, or a silicon germanium (SiGe) semiconductor.

According to an example embodiment of the present disclosure, a semiconductor device may include a stack structure including interlayer insulating layers and conductive layers alternately stacked in a vertical direction; a vertical structure in a channel hole penetrating the stack structure; and a contact plug connected to the vertical structure and on the vertical structure. The conductive layers may include a plurality of lower gate electrodes, a plurality of intermediate gate electrodes on the plurality of lower gate electrodes, and a plurality of upper gate electrodes on the plurality of intermediate gate electrodes. The vertical structure may include a first semiconductor layer facing the plurality of lower gate electrodes, the plurality of intermediate gate electrodes, and the plurality of upper gate electrodes; a second semiconductor layer at a higher level than the plurality of intermediate gate electrodes and facing at least one erase control gate electrode among the plurality of upper gate electrodes; and a conductive pad pattern spaced apart from the first semiconductor layer and in contact with the second semiconductor layer. The first semiconductor layer may include a first oxide semiconductor having a band gap larger than a band gap of a silicon semiconductor. The second semiconductor layer may include at least one of a second oxide semiconductor, a silicon (Si) semiconductor, a germanium (Ge) semiconductor, or a silicon germanium (SiGe) semiconductor.

According to an example embodiment of the present disclosure, a data storage system may include a semiconductor device including an input/output pad; and a controller electrically connected to the semiconductor device through the input/output pad, the controller being configured to control the semiconductor device. The semiconductor device may include a peripheral structure including a peripheral circuit, and a memory structure vertically overlapping the peripheral structure. The memory structure may include a stack structure, a vertical structure, and a contact plug on the vertical structure. The stack structure may include interlayer insulating layers and conductive layers alternately stacked in a vertical direction, and the vertical structure may be in a channel hole penetrating the stack structure. The conductive layers may include a plurality of lower gate electrodes, a plurality of intermediate gate electrodes on the plurality of lower gate electrodes, and a plurality of upper gate electrodes on the plurality of intermediate gate electrodes. The vertical structure may include a dielectric structure covering a sidewall of the channel hole and including a data storage layer, a first semiconductor layer covering an internal side surface of the dielectric structure, a conductive pad pattern connected to the contact plug, an insulating core pattern below the conductive pad pattern, and a second semiconductor layer between the first semiconductor layer and the conductive pad pattern. A first portion of the first semiconductor layer may be between the conductive pad pattern and the dielectric structure and a second portion of the first semiconductor layer may be between the insulating core pattern and the dielectric structure. A lower end of the second semiconductor layer may be at a higher level than the plurality of intermediate gate electrodes and at a lower level than a first upper erase control gate electrode among the plurality of upper gate electrodes. An upper end of the second semiconductor layer may be at a higher level than the first upper erase control gate electrode. The first semiconductor layer may include a first oxide semiconductor having N-type conductivity. The second semiconductor layer may include at least one of a second oxide semiconductor, a silicon (Si) semiconductor, a germanium (Ge) semiconductor, or a silicon germanium (SiGe) semiconductor.

According to an example embodiment of the present disclosure, a method of manufacturing a semiconductor device may include forming a mold structure on a substrate, the mold structure including mold layers and interlayer insulating layer alternately stacked on the substrate; forming a channel hole penetrating through the mold structure in a vertical direction and extending partially into the substrate; forming a vertical structure in the channel hole; and replacing the mold layers with conductive layers and dielectric layers surrounding the conductive layers. The vertical structure may include an insulating core pattern, a conductive pad pattern on the insulating core pattern, a first semiconductor layer surrounding the insulating core pattern and the conductive pad pattern, a dielectric structure between the first semiconductor layer and a sidewall of the channel hole, and a second semiconductor layer with a first portion of the second semiconductor layer between the first semiconductor layer and the conductive pad pattern and a second portion of the second semiconductor layer between the conductive pad pattern and the insulating core pattern. The conductive layers may include a plurality of lower gate electrodes, a plurality of intermediate gate electrodes on the plurality of lower gate electrodes, and a plurality of upper gate electrodes on the plurality of intermediate gate electrodes. A lower end of the second semiconductor layer may be at a higher level than the plurality of intermediate gate electrodes and at a lower level than a first upper erase control gate electrode among the plurality of upper gate electrodes. An upper end of the second semiconductor layer may be at a higher level than the first upper erase control gate electrode. The first semiconductor layer may include a first oxide semiconductor having N-type conductivity. The second semiconductor layer may include at least one of a second oxide semiconductor, a silicon (Si) semiconductor, a germanium (Ge) semiconductor, or a silicon germanium (SiGe) semiconductor.

In some embodiments, the replacing the mold layers with conductive layers may include forming an isolation trench penetrating the mold structure in the vertical direction and extending partially in the substrate, the isolation trench being spaced apart from the channel hole in a direction parallel to an upper surface of the substrate; replacing the mold layers exposed by the isolation trench with the conductive layers and the dielectric layers surrounding the conductive layers; and filling the isolation trench with an isolation structure.

In some embodiments, the method may further include forming a contact plug electrically connected to the conductive pad pattern; forming a bit line connected to the contact plug; and forming a peripheral circuit on the bit line, the peripheral circuit being part of a peripheral structure.

In some embodiments, the method may further include removing the substrate to expose a lower portion of the vertical structure; and forming a third semiconductor and a source structure in contact with the lower portion of the vertical structure.

In some embodiments, the second semiconductor layer may include the second oxide semiconductor, and the second oxide semiconductor may have P-type conductivity.

### BRIEF DESCRIPTION OF DRAWINGS

The above and other aspects, features, and advantages of the present disclosure will be more clearly understood from the following detailed description, taken in combination with the accompanying drawings, in which:

FIGS. 1, 2, 3A and 3B are diagrams illustrating a semiconductor device according to example embodiments of the present disclosure;

FIG. 4 is an enlarged cross-sectional diagram illustrating a portion of a semiconductor device according to an example embodiment of the present disclosure;

FIG. 5 is an enlarged cross-sectional diagram illustrating a portion of a semiconductor device according to an example embodiment of the present disclosure;

FIG. 6 is an enlarged cross-sectional diagram illustrating a portion of a semiconductor device according to an example embodiment of the present disclosure;

FIG. 7 is an enlarged cross-sectional diagram illustrating a portion of a semiconductor device according to an example embodiment of the present disclosure;

FIG. 8 is an enlarged cross-sectional diagram illustrating a portion of a semiconductor device according to an example embodiment of the present disclosure;

FIG. 9A is an energy band diagram illustrating an example of a semiconductor device according to an example embodiment of the present disclosure;

FIG. 9B is an energy band diagram illustrating an example of a semiconductor device according to an example embodiment of the present disclosure;

FIG. 9C is an energy band diagram illustrating an example of a semiconductor device according to an example embodiment of the present disclosure;

FIG. 9D is an energy band diagram illustrating an example of a semiconductor device according to an example embodiment of the present disclosure;

FIGS. 10, 11, 12, and 13 are cross-sectional diagrams illustrating and example of a method of forming a semiconductor device according to an example embodiment of the present disclosure;

FIG. 14 is a diagram illustrating a data storage system including a semiconductor device according to an example embodiment of the present disclosure;

FIG. 15 is a diagram illustrating a data storage system including a semiconductor device according to an example embodiment of the present disclosure; and

FIG. 16 is a diagram illustrating a data storage system including a semiconductor device according to an example embodiment of the present disclosure.

### DETAILED DESCRIPTION

Hereinafter, terms such as “upper,” “middle”, “intermediate”, “lower,”, “uppermost”, “lowermost” “inner,” and “outer” may be replaced with other terms, for example, “first,” “second,” and “third,” to describe the elements of the specification. Terms like “first,” “second,” and “third” may be used to describe various elements, but the elements are not limited by these terms. For example, a “first element” may be referred to as a “second element” or named using other terms distinguishable from other elements. The size ratios, width ratios, length ratios, and the like between elements shown in the drawings can be understood from the drawings themselves, even without additional explanation.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

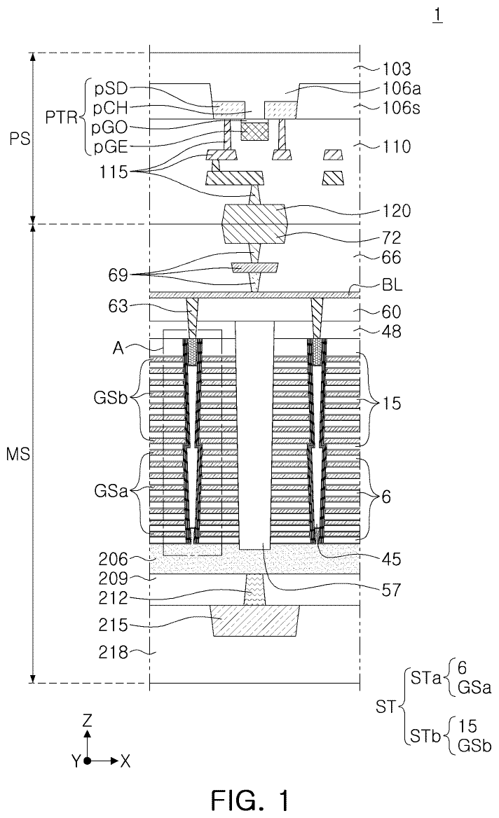

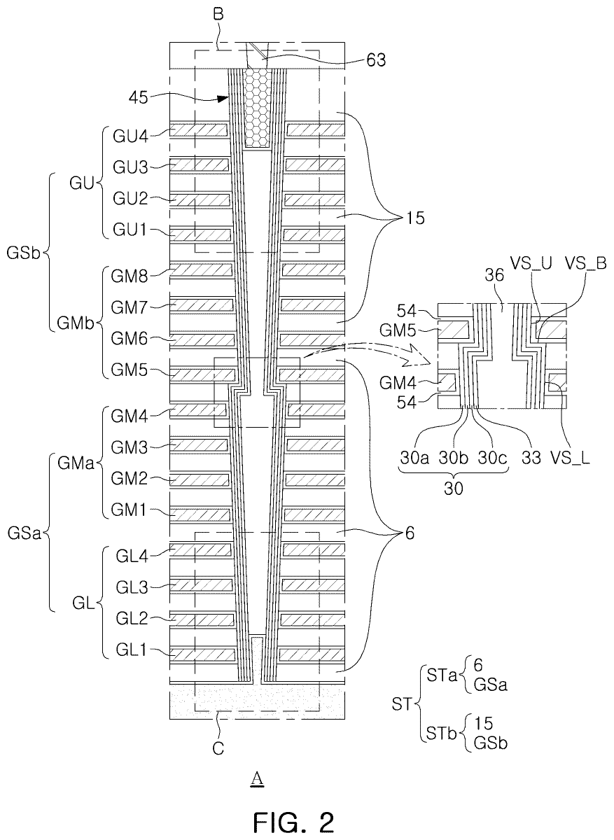

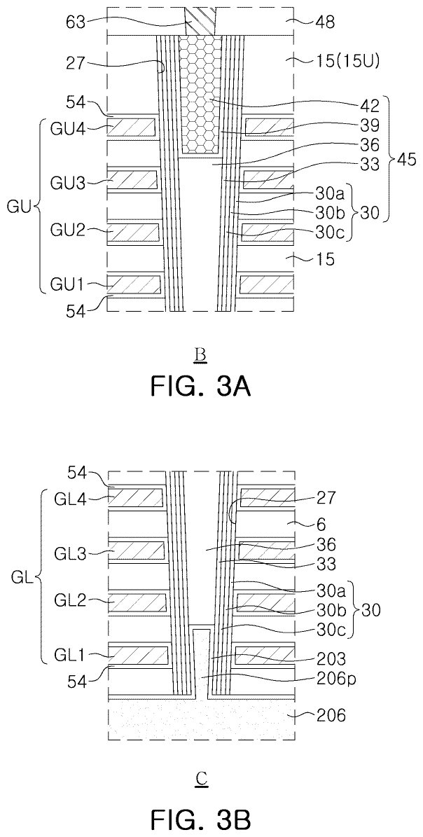

A semiconductor device according to example embodiments will be described with reference to FIGS. 1, 2, 3A, and 3B. In FIGS. 1, 2, 3A, and 3B, FIG. 1 is a cross-sectional diagram illustrating a semiconductor device according to example embodiments, FIG. 2 is an enlarged diagram illustrating portion ‘A’ in FIG. 1, FIG. 3A is an enlarged diagram illustrating portion ‘B’ in FIG. 2, and FIG. 3B is an enlarged diagram illustrating portion ‘C’ in FIG. 2.

Referring to FIGS. 1, 2, 3A, and 3B, a semiconductor device 1 according to example embodiments may include a memory structure MS and a peripheral structure PS vertically overlapping the memory structure MS. In an example, the peripheral structure PS may be disposed on the memory structure MS.

The memory structure MS may include a stack structure ST, a vertical structure 45, a contact plug 63, and a bit line BL.

The stack structure ST may include a first stack structure STa and a second stack structure STb on the first stack structure STa. The first stack structure STa may include first interlayer insulating layers 6 and first conductive layers GSa, alternately stacked in the vertical direction Z. The second stack structure STb may include second interlayer insulating layers 15 and second conductive layers GSb, alternately stacked in the vertical direction Z. Accordingly, the stack structure ST may include interlayer insulating layers 6 and 15 and conductive layers GSa and GSb, alternately and repeatedly stacked in the vertical direction Z. The conductive layers GSa and GSb may be stacked and spaced apart from each other in the vertical direction Z. Each of the conductive layers GSa and GSb may include at least one of polysilicon, W, Ru, Mo, Ni, NiSi, TiSi, WSi, Co, CoSi, Ti, Ta, TiN, TaN, or WN.

The first conductive layers GSa may include a plurality of lower gate electrodes GL and the plurality of first intermediate gate electrodes GMa on the lower gate electrodes GL. The second conductive layers GSb may include a plurality of second intermediate gate electrodes GMb on the first intermediate gate electrodes GMa, and a plurality of upper gate electrodes GU on the second intermediate gate electrodes GMb. The first intermediate gate electrodes GMa and the second intermediate gate electrodes GMb may form a plurality of intermediate gate electrodes GMa and GMb. Accordingly, the conductive layers GSa and GSb may include a plurality of lower gate electrodes GL, a plurality of intermediate gate electrodes GMa and GMb, and a plurality of upper gate electrodes GU.

The plurality of lower gate electrodes GL may include first to fourth lower gate electrodes GL1, GL2, GL3, and GL4, stacked in order in the vertical direction Z. The first intermediate gate electrodes GMa may include first to fourth intermediate gate electrodes GM1, GM2, GM3, and GM4, stacked in order in the vertical direction Z. The second intermediate gate electrodes GMb may include fifth to eighth intermediate gate electrodes GM5, GM6, GM7, and GM8, stacked in order in the vertical direction Z. The plurality of upper gate electrodes GU may include first to fourth upper gate electrodes GU1 and GU2, GU3, and GU4, stacked in order in the vertical direction Z.

Among the interlayer insulating layers 6 and 15 and the conductive layers GSa and GSb, the uppermost layer may be configured as an uppermost interlayer insulating layer, and the lowermost layer configured as a lowermost interlayer insulating layer.

In example embodiments, the number of the conductive layers GSa and GSb illustrated in the diagram is an example, and the number of the conductive layers GSa and GSb may be different from the number illustrated in the diagram.

The plurality of lower gate electrodes GL may include at least one lower erase control gate electrode and at least one lower select gate electrode. For example, at least one of the first and second lower gate electrodes GL1 and GL2 may be configured as a lower erase control gate electrode, and at least one of the third and fourth lower gate electrodes GL3 and GL3 may be configured as a lower select gate electrode. For example, the first lower gate electrode GL1, which may be a lowermost gate electrode, may be configured as a lower erase control gate electrode.

The plurality of intermediate gate electrodes GMa and GMb may include word lines.

The plurality of upper gate electrodes GU may include at least one upper erase control gate electrode and at least one upper select gate electrode. For example, at least one of the third and fourth upper gate electrodes GU3 and GU4 may be a lower erase control gate electrode, and at least one of the first and second upper gate electrodes GU1 and GU2 may be a string select gate electrode for selecting a string. For example, the fourth upper gate electrode GU4, which may be an uppermost gate electrode, may be a first upper erase control gate electrode.

The vertical structure 45 may be disposed in the channel hole 27 penetrating the stack structure ST. The vertical structure 45 may include a dielectric structure 30, a first semiconductor layer 33, an insulating core pattern 36, a conductive pad pattern 42, and a second semiconductor layer 39.

The dielectric structure 30 may cover a sidewall of the channel hole 27. The dielectric structure 30 may include a first dielectric layer 30a, a second dielectric layer 30c, and a data storage layer 30b between the first dielectric layer 30a and the second dielectric layer 30c. Upper surfaces of the first dielectric layer 30a, the data storage layer 30b, and the second dielectric layer 30c may be coplanar with each other. The lower surfaces of the first dielectric layer 30a, the data storage layer 30b, and the second dielectric layer 30c may be coplanar with each other.

The upper surface of the dielectric structure 30 may be at a higher level than the uppermost conductive layer GU4 among the conductive layers GSa and GSb, and the lower surface of the dielectric structure 30 may be at a lower level than the conductive layer GL1 of the lowermost among the conductive layers GSa and GSb. Upper surface of the dielectric structure 30 may be coplanar with an upper surface of the stack structure ST. A lower surface of the dielectric structure 30 may be coplanar with a lower surface of the stack structure ST.

The first dielectric layer 30a may include at least one of silicon oxide and a high-κ material. The second dielectric layer 30c may include silicon oxide or silicon oxide doped with impurities.

The data storage layer 30b of the dielectric structure 30 may include at least one of a first data storage material layer for trapping charges and storing data and a second data storage material layer for storing data using a ferroelectric material.

In an example, the data storage layer 30b of the dielectric structure 30 may include the first data storage material layer for trapping charges and storing data, for example, silicon nitride. The data storage layer 30b may include regions for storing data in a semiconductor device, such as a flash memory device.

In an example, the data storage layer 30b of the dielectric structure 30 may include a second data storage material layer including a ferroelectric material. The second data storage material layer may have polarization properties that depend on an electric field, and may have a remnant polarization by a dipole even in the absence of an external electric field. The second data storage material layer may record data using a polarization state in the ferroelectric layer. The second data storage material layer may be a ferroelectric layer including a Hf-based compound, a Zr-based compound, and/or a Hf—Zr-based compound. For example, the Hf-based compound may be a HfO-based ferroelectric material, the Zr-based compound may include a ZrO-based ferroelectric material, and the Hf—Zr-based compound may include a hafnium zirconium oxide (HZO)-based ferroelectric material.

In an example, the data storage layer 30b of the dielectric structure 30 may include a first data storage material layer for storing data by trapping charge and a second data storage material layer for storing data using a ferroelectric material.

The first semiconductor layer 33 may cover an internal side surface of the dielectric structure 30. An upper surface of the first semiconductor layer 33 may be coplanar with an upper surface of the dielectric structure 30. A lower surface of the first semiconductor layer 33 may be coplanar with a lower surface of the dielectric structure 30. The first semiconductor layer 33 may be in contact with the dielectric structure 30. The first semiconductor layer 33 may be in contact with the second dielectric layer 30c of the dielectric structure 30.

The insulating core pattern 36 may have an upper surface at a higher level than the plurality of intermediate conductive layers GMa and GMb and a level lower than a level of the fourth upper conductive layer GU4. The insulating core pattern 36 may have a lower surface at a lower level than the plurality of intermediate conductive layers GMa and GMb. The lower surface of the insulating core pattern 36 may be at a higher level than the first lower conductive layer GL. The insulating core pattern 36 may include an insulating material such as silicon oxide.

The conductive pad pattern 42 may be disposed on the insulating core pattern 36. An upper surface of the conductive pad pattern 42 may be coplanar with upper surfaces of the first semiconductor layer 33 and the dielectric structure 30 with each other. The lower surface of the conductive pad pattern 42 may be at a lower level than the fourth upper conductive layer GU4.

In an example, the conductive pad pattern 42 may include at least one of a conductive metal oxide (e.g., indium tin oxide (ITO)), doped polysilicon, a metal nitride (e.g., TiN, WN, TaN, or the like), a metal (e.g., W, Mo, Ni, Ti, Ta, or the like), and a metal-semiconductor compound (e.g., TiSi, CoSi, WSi, or the like).

In an example, the conductive pad pattern 42 may include a metallic material and may not include a doped semiconductor. The conductive pad pattern 42 may be formed of a metallic material not having N-type conductivity or P-type conductivity. For example, the conductive pad pattern 42 may include at least one of a conductive metal oxide (e.g., indium tin oxide (ITO)), a metal nitride (e.g., TiN, WN, TaN, or the like), a metal (e.g., W, Mo, Ni, Ti, Ta, or the like), and a metal-semiconductor compound (e.g., TiSi, CoSi, WSi, or the like).

At least a portion of the first semiconductor layer 33 may be disposed between the conductive pad pattern 42 and the dielectric structure 30, and between the insulating core pattern 36 and the dielectric structure 30. The first semiconductor layer 33 may face the plurality of lower gate electrodes GL, the plurality of intermediate gate electrodes GMa and GMb, and the plurality of upper gate electrodes GU.

The second semiconductor layer 39 may be disposed between the conductive pad pattern 42 and the first semiconductor layer 33. The second semiconductor layer 39 may extend from a portion disposed between the conductive pad pattern 42 and the first semiconductor layer 33 to a lower surface of the conductive pad pattern 42 and an upper surface of the insulating core pattern 36.

The second semiconductor layer 39 may be at a higher level than the plurality of intermediate gate electrodes GMa and GMb and may face at least one erase control gate electrode GU4 among the plurality of upper gate electrodes GU. The at least one erase control gate electrode GU4 may be the fourth upper gate electrode GU4 or the third and fourth upper gate electrodes GU3 and GU4.

A lower end of the second semiconductor layer 39 may be at a higher level than the plurality of intermediate gate electrodes GMa and GMb and may be at a lower level than the fourth upper gate electrode GU4, which may be the erase control gate electrode.

The second semiconductor layer 39 may be at a higher level than at least one of the first and second upper gate electrodes GU1 and GU2, which may be string select gate electrodes.

The first semiconductor layer 33 and the second semiconductor layer 39 may have different band gaps. For example, the first semiconductor layer 33 may have a first band gap, and the second semiconductor layer 39 may have a second band gap smaller than the first band gap. The band gap is the energy difference between the highest energy level of the valance band and the lowest energy level of the conduction band in the energy band diagram of a semiconductor.

At least one of the first semiconductor layer 33 and the second semiconductor layer 39 may include an oxide semiconductor having a band gap larger than a band gap of a silicon semiconductor.

In an example, the first semiconductor layer 33 may include a first oxide semiconductor layer. For example, the first oxide semiconductor layer of the first semiconductor layer 33 may have N-type conductivity. For example, the first oxide semiconductor layer of the first semiconductor layer 33 may include at least one of ZnO, In₂O₃, SnO₂, Ga₂O₃, TiO₂, indium-gallium oxide (IGO), and indium-gallium-zinc oxide (IGZO) having N-type conductivity. The first oxide semiconductor layer of the first semiconductor layer 33 may have defects such as oxygen vacancy or interstitial metal atoms. The first oxide semiconductor layer of the first semiconductor layer 33 may include impurities which may provide electrons, that is, a donor. For example, the ZnO of the first semiconductor layer 33 may include Al, Ga, or In as impurities, that is, a donor, and SnO₂ of the first semiconductor layer 33 may include impurities, that is, a halogen element, such as F, as a donor.

The second semiconductor layer 39 may include at least one of a second oxide semiconductor, a silicon (Si) semiconductor, a germanium (Ge) semiconductor, and a silicon germanium (SiGe) semiconductor.

In an example, the second semiconductor layer 39 may have P-type conductivity.

In an example, the second semiconductor layer 39 may not have P-type conductivity, and may include a semiconductor material having a relatively small band gap such that electron-hole pairs may be easily generated in a bonding surface with the first semiconductor layer 33.

In an example, the second semiconductor layer 39 may not have P-type conductivity, and may include a semiconductor material having a small band gap such that electron-hole pairs may be generated more easily in a bonding surface with the first semiconductor layer 33 when a positive voltage is applied to the conductive pad pattern 42 in an erase operation.

In an example, the second semiconductor layer 39 may include a semiconductor material not having P-type conductivity, and may provide a region having high defect density such that electron-hole pairs may be generated more easily in a bonding surface with the first semiconductor layer 33 when a positive voltage is applied to the conductive pad pattern 42 in an erase operation.

At least one of a second oxide semiconductor, silicon (Si) semiconductor, germanium (Ge) semiconductor, and silicon germanium (SiGe) semiconductor of the second semiconductor layer 39 may have P-type conductivity. At least one of a second oxide semiconductor, silicon (Si) semiconductor, germanium (Ge) semiconductor, and silicon germanium (SiGe) semiconductor of the second semiconductor layer 39 may have a small band gap such that electron-hole pairs may be more easily generated in a bonding surface with the first semiconductor layer 33. At least one of a second oxide semiconductor, silicon (Si) semiconductor, germanium (Ge) semiconductor, and silicon germanium (SiGe) semiconductor of the second semiconductor layer 39 may not have P-type conductivity, and may provide a region having high defect density such that electron-hole pairs may be easily be generated in a bonding surface with the first semiconductor layer 33 when a positive voltage is applied to the conductive pad pattern 42. Here, silicon (Si), germanium (Ge), and silicon-germanium (SiGe) may be polysilicon (Si), polygermanium (Ge), and polysilicon-germanium (SiGe).

In an example, the second oxide semiconductor of the second semiconductor layer 39 may have N-type conductivity or P-type conductivity due to defects or impurities. The second oxide semiconductor of the second semiconductor layer 39 may also have intrinsic semiconductor properties.

In an example, at least one of silicon (Si) semiconductor, germanium (Ge) semiconductor, and silicon germanium (SiGe) semiconductor of the second semiconductor layer 39 may have intrinsic semiconductor properties, or may have P-type conductivity due to impurities.

In an example, the second semiconductor layer 39 may include a second oxide semiconductor layer having a band gap smaller than that of the first semiconductor layer 33, or having a defect density larger than that of the first semiconductor layer 33. The second oxide semiconductor layer of the second semiconductor layer 39 may have P-type conductivity. For example, the second oxide semiconductor layer of the second semiconductor layer 39 may include at least one of Cu₂O, CuO, NiO, CuAlO₂, CuCrO₂, Co₃O₄, and SnO having P-type conductivity.

The contact plug 63 may be disposed on the vertical structure 45. The contact plug 63 may be electrically connected to the conductive pad pattern 42 of the vertical structure 45. The contact plug 63 may be formed of a conductive material. The contact plug 63 may be in contact with the conductive pad pattern 42 of the vertical structure 45. The bit line BL may be electrically connected to the contact plug 63 on the contact plug 63.

The vertical structure 45 may include a lower vertical portion VS_L, an upper vertical portion VS_U on the lower vertical portion VS_L, and a bonding portion VS_B between the lower vertical portion VS_L and the upper vertical portion VS_U.

In the vertical structure 45, the bonding portion VS_B may be disposed between the first intermediate gate electrodes GMa and the second intermediate gate electrodes GMb. For example, the bonding portion VS_B may be disposed between the fourth intermediate gate electrode GM4 and the fifth intermediate gate electrode GM5. In the vertical structure 45, the bonding portion VS_B may be bent from a side surface of the lower vertical portion VS_L and a side surface of the upper vertical portion VS_U.

The memory structure MS may further include a dielectric layer 54 covering upper and lower surfaces of each of the conductive layers GSa and GSb, and extending between a side surface of each of the conductive layers GSa and GSb and the vertical structure 45. The dielectric layer 54 may include at least one of silicon oxide and a high-κ material.

The memory structure MS may further include a source structure 206, a protruding conductive pattern 206p and a third semiconductor layer 203.

The source structure 206 may be disposed below the stack structure ST. The source structure 206 may include a silicon layer having N-type conductivity. The source structure 206 may include a polysilicon layer and a metal layer below the polysilicon layer. The protruding conductive pattern 206p may extend from the source structure 206 into the channel hole 27 in a direction toward the insulating core pattern 36.

The third semiconductor layer 203 may be disposed between the protruding conductive pattern 206p and the first semiconductor layer 33. An upper end of the third semiconductor layer 203 may be at a lower level than the plurality of intermediate gate electrodes GMa and GMb and at a higher level than the first lower gate electrode GL1, which may be the lower erase control gate electrode.

The third semiconductor layer 203 may extend from a portion disposed between the protruding conductive pattern 206p and the first semiconductor layer 33 to a region between an upper surface of the protruding conductive pattern 206p and a lower surface of the insulating core pattern 36. The third semiconductor layer 203 may extend from a portion disposed between the protruding conductive pattern 206p and the first semiconductor layer 33 to a region between a lower surface of the stack structure ST and an upper surface of the source structure 206.

The third semiconductor layer 203 may have a band gap different from a band gap of the first semiconductor layer 33. The band gap of the third semiconductor layer 203 may be smaller than the band gap of the first semiconductor layer 33.

In an example, the third semiconductor layer 203 may have P-type conductivity.

In an example, the third semiconductor layer 203 may not have P-type conductivity, and may include a semiconductor material having a relatively small band gap such that electron-hole pairs may easily be generated in a bonding surface with the first semiconductor layer 33.

In an example, the third semiconductor layer 203 may not have P-type conductivity, and may include a semiconductor material having a relatively small band gap such that electron-hole pairs may easily be generated in a bonding surface with the first semiconductor layer 33 when a positive voltage is applied to the source structure 206 in an erase operation.

In an example, the third semiconductor layer 203 may include a semiconductor material not having P-type conductivity, and may provide a region having a high defect density such that electron-hole pairs may be generated more easily in a bonding surface with the first semiconductor layer 33 when a positive voltage is applied to the source structure 206 in an erase operation.

In an example, the third semiconductor layer 203 may include at least one of an oxide semiconductor, silicon (Si), germanium (Ge), and silicon-germanium (SiGe).

In an example, the third semiconductor layer 203 may include the same semiconductor material as the second semiconductor layer 39.

The memory structure MS may further include an insulating layer 209 below the source structure 206, a conductive via 212 penetrating the insulating layer 209 and electrically connected to the source structure 206, a source interconnection 215 electrically connected to the conductive via 212 below the insulating layer 209, and an insulating layer 218 covering the source interconnection 215 below the insulating layer 209.

The memory structure MS may further include a first insulating layer 48 on the stack structure ST, and a second insulating layer 60 on the first insulating layer 48.

The contact plug 63 may penetrate the first and second insulating layers 48 and 60. The bit line BL may be electrically connected to the contact plug 63 on the second insulating layer 60.

The memory structure MS may further include an isolation structure 57 penetrating the stack structure ST and the first insulating layer 48. The bit line BL may extend in a first horizontal direction X, and the isolation structure 57 may extend in a second horizontal direction Y perpendicular to the first horizontal direction X.

The memory structure MS may further include an insulating structure 66 covering the bit line BL on the second insulating layer 60, an interconnection structure 69 buried in the insulating structure 66, and a first bonding pad 72 electrically connected to the interconnection structure 69 and having an upper surface coplanar with an upper surface of the insulating structure 66.

The peripheral structure PS may include a substrate 103, a peripheral active region 106a below the substrate 103, and a peripheral device separation region 106s defining the peripheral active region 106a below the substrate 103. The substrate 103 may be a semiconductor substrate.

The peripheral structure PS may further include a peripheral circuit PTR below the substrate 103, a peripheral interconnection structure 115, a second bonding pad 120, and an insulating structure 110.

The peripheral circuit PTR may include a peripheral transistor. The peripheral transistor of the peripheral circuit PTR may include peripheral source/drain regions pSD spaced apart from each other in the peripheral active region 106a, a peripheral channel region pCH between the peripheral source/drain regions pSD, and a peripheral gate pGO and pGE below the peripheral active region 106a.

The peripheral gate pGO and pGE may include a peripheral gate dielectric layer pGO and a peripheral gate electrode pGE below the peripheral gate dielectric layer pGO. The peripheral interconnection structure 115 may be buried in the insulating structure 110 and may be electrically connected to the peripheral circuit PTR. The second bonding pad 120 may have upper surfaces coplanar with an upper surface of the insulating structure 110 and may be electrically connected to the peripheral interconnection structure 115.

The insulating structure 66 of the memory structure MS and the insulating structure 110 of the peripheral structure PS may be in contact with and bonded to each other. The first bonding pad 72 and the second bonding pad 120 may include a metal material and may be bonded to each other. For example, the first bonding pad 72 and the second bonding pad 120 may include copper (Cu), and copper of the first bonding pad 72 and copper of the second bonding pad 120 may be in contact with and bonded to each other.

Hereinafter, various example embodiments of the semiconductor device 1 will be described. The various example embodiments described below and the example embodiments described above may be combined and may be provided as an example embodiment. Hereinafter, components described above may be directly cited without a detailed description, or the description may not be provided. Also, components described below, which may be modified or replaced will be described with reference to the diagrams as below, but the modified, replaced, or added components may be combined with each other or combined with the components described above and may be provided as a semiconductor device according to an example embodiment.

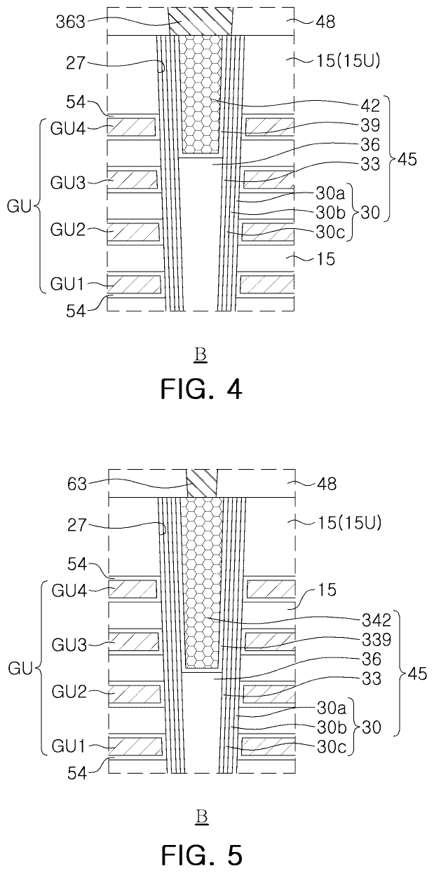

FIG. 4 is an enlarged cross-sectional diagram illustrating a portion of a semiconductor device according to an example embodiment.

In an example, referring to FIG. 4, the contact plug (63 in FIGS. 2 and 3A) described above may be replaced with a contact plug 363 connected to the first semiconductor layer 33, the second semiconductor layer 39, and the conductive pad pattern 42. The contact plug 363 may be in contact with the first semiconductor layer 33, the second semiconductor layer 39, and the conductive pad pattern 42.

FIG. 5 is an enlarged diagram illustrating a modified example of the region ‘B’ in FIG. 2.

In an example, referring to FIG. 5, the fourth upper gate electrode GU4 may be the first upper erase control gate electrode, and the third upper gate electrode GU3 may be the second upper erase control gate electrode.

The conductive pad pattern (42 in FIGS. 2 and 3A) described above may be replaced with a conductive pad pattern 342 having a lower surface at a lower level than the third upper gate electrode GU3, which may be the second upper erase control gate electrode.

The second semiconductor layer (39 in FIGS. 2 and 3A) described above may be modified to a second semiconductor layer 339 including a portion disposed between the conductive pad pattern 342 and the first semiconductor layer 33 and a portion disposed between the conductive pad pattern 342 and the insulating core pattern 36.

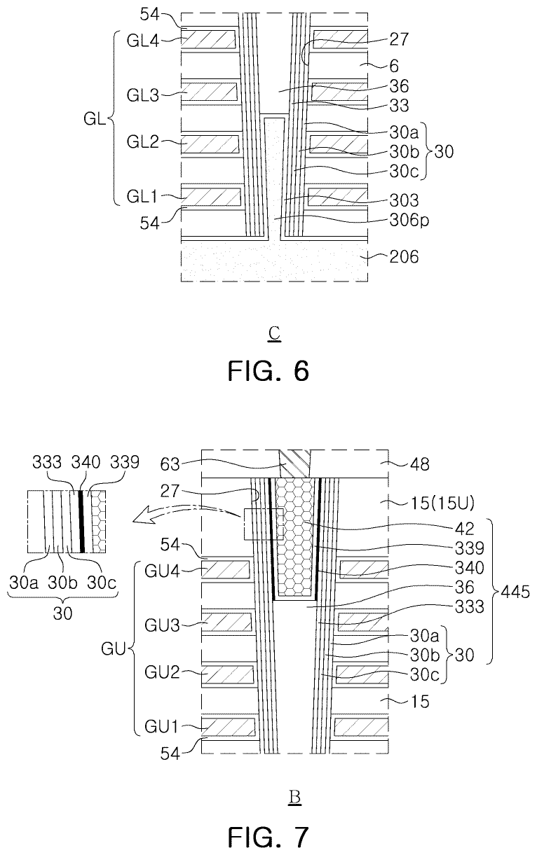

FIG. 6 is an enlarged diagram illustrating a modified example of region ‘C’ in FIG. 2.

In an example, referring to FIG. 6, the first lower gate electrode GL1 may be a first lower erase control gate electrode, and the second lower gate electrode GL2 may be a second lower erase control gate electrode.

The protruding conductive pattern (206p in FIG. 2 and FIG. 3B) described above may be modified into a protruding conductive pattern 306p having an upper surface at a higher level than the second lower gate electrode GL2, which may be the second lower erase control gate electrode.

The third semiconductor layer (203 in FIGS. 2 and 3B) described above may be modified to a third semiconductor layer 303 including a portion disposed between the protruding conductive pattern 306p and the first semiconductor layer 33 and a portion disposed between the source structure 206 and the stack structure ST.

FIG. 7 is an enlarged diagram illustrating a modified example of region ‘B’ in FIG. 2.

In an example, referring to FIG. 7, the vertical structure (45 in FIGS. 2 and 3A) described above may be modified to a vertical structure 445 including a metal layer 340 as in FIG. 7. For example, the vertical structure 445 may include the insulating core pattern 36 and the conductive pad pattern 42 described above, a first semiconductor layer 333 which may correspond to the first semiconductor layer (33 in FIG. 2 and FIG. 3A) described above, a second semiconductor layer 339 which may correspond to the second semiconductor layer (39 in FIG. 2 and FIG. 3A) described above, and a metal layer 340 disposed between the first semiconductor layer 333 and the second semiconductor layer 339. The metal layer 340 may be in contact with the first semiconductor layer 333 and the second semiconductor layer 339. The second semiconductor layer 339 may cover a side surface and a lower surface of the conductive pad pattern 42. A thickness of the metal layer 340 may be less than a thickness of the first semiconductor layer 333 and a thickness of the second semiconductor layer 339.

The first semiconductor layer 333 may include a first oxide semiconductor including a first metal element, the second semiconductor layer 339 may include a second oxide semiconductor including a second metal element different from the first metal element, and the metal layer 340 may include a metal including at least one of the first metal element and the second metal element. For example, the first semiconductor layer 333 may include at least one of ZnO, In₂O₃, SnO₂, Ga₂O₃, indium-gallium oxide (IGO), and indium-gallium-zinc oxide (IGZO), similarly to the first semiconductor layer described above (33 in FIGS. 2 and 3A), the second semiconductor layer 339 may include at least one of Cu₂O, CuO, NiO, CuAlO₂, CuCrO₂, Co₃O₄, and SnO, similarly to the second semiconductor layer described above (39 in FIGS. 2 and 3A), and the metal layer 340 may include at least one of the first metal element of the first oxide semiconductor of the first semiconductor layer 333 and the second metal element of the second oxide semiconductor of the second semiconductor layer 339. For example, the first semiconductor layer 333 may include a ZnO layer, the second semiconductor layer 339 may include a CuO layer, and the metal layer 340 may include a Cu layer. The metal layer 340 may be formed by precipitation of a metal element in the second semiconductor layer 339.

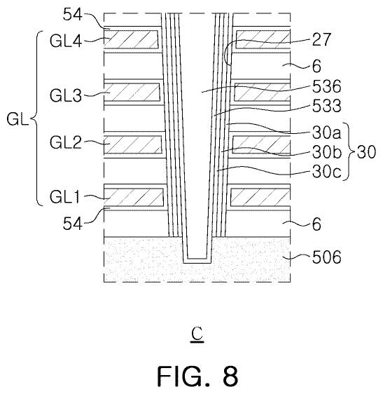

FIG. 8 is an enlarged diagram illustrating a modified example of region ‘C’ in FIG. 2.

In an example, referring to FIG. 8, the insulating core pattern (36 in FIG. 2 and FIG. 3B) described above may be replaced with an insulating core pattern 536 extending below the channel hole 27, and the first semiconductor layer (33 in FIG. 2 and FIG. 3B) described above may be replaced with a first semiconductor layer 533 extending to cover a lower surface of the insulating core pattern 536. The source structure 206 described above may be replaced with a source structure 506 in contact with the first semiconductor layer 533 and in contact with a lower surface of the dielectric structure 30.

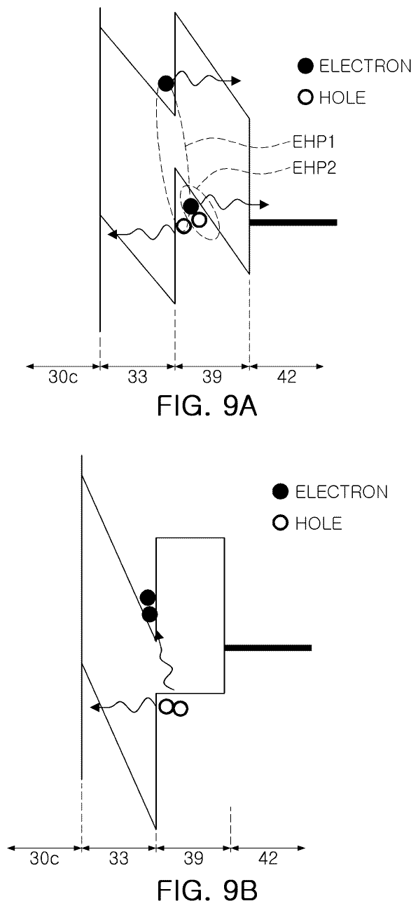

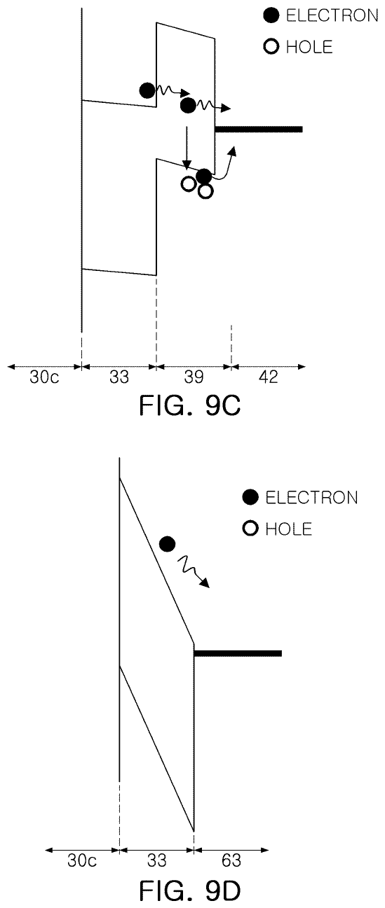

In the description below, referring to FIGS. 3A 9A, an erase operation of a semiconductor device according to an example embodiment will be described. FIG. 9A is an energy band diagram illustrating an erase operation of a semiconductor device in FIG. 3A.

Referring to FIG. 3A and FIG. 9A, for an erase operation, a first erase voltage may be applied to the bit line (BL in FIG. 1), a second erase voltage may be applied to the common source structure 206, and a third erase voltage may be applied to the fourth upper gate electrode GU4, which may be an erase control gate electrode.

The first semiconductor layer 33 may be a first oxide semiconductor layer having N-type conductivity, and the second semiconductor layer 39 may be a second oxide semiconductor layer having P-type conductivity. In the first semiconductor layer 33, a major carrier may be an electron, and current may flow as electrons move in the conduction band. In the second semiconductor layer 39, a major carrier may be a hole, and current may flow as holes move in the valence band. Tunneling may be a phenomenon in which charge carriers move across a band gap barrier, and electrons may tunnel from N-type to P-type, or holes may tunnel from P-type to N-type.

In an example, to increase conduction efficiency in forward current driven by major carrier conduction and/or forward current driven by valance band electron tunneling during an erase operation, the first semiconductor layer 33 may be formed of an N-type first oxide semiconductor having a band gap larger than the band gap of a silicon semiconductor, and the second semiconductor layer 39 may be formed of a P-type second oxide semiconductor layer having a band gap larger than the band gap of a silicon semiconductor and a band edge having a small difference from the band edge of the first oxide semiconductor. Accordingly, since the difference between the band edge of the first oxide semiconductor of the first semiconductor layer 33 and the band edge of the second oxide semiconductor of the second semiconductor layer 39 is relatively small, a band offset between the first semiconductor layer 33 and the second semiconductor layer 39 may be relatively small. Accordingly, by reducing the band offset between the first and second semiconductor layers 33 and 39, tunneling efficiency of charge carriers may be increased, and current may flow efficiently. For example, during an erase operation, in the first electron-hole pair EHP1 generated by forward current driven by major carrier conduction, an electron may move from the first semiconductor layer 33 to the second semiconductor layer 39, and a hole may move from the second semiconductor layer 39 to the first semiconductor layer 33. Furthermore, during an erase operation, in the second electron-hole pair EHP2 generated by forward current driven by valance band electron tunneling, an electron may move from the first semiconductor layer 33 to the second semiconductor layer 39, and a hole may move from the second semiconductor layer 39 to the first semiconductor layer 33.

In an example, to increase conduction efficiency in forward current driven by major carrier conduction and/or forward current driven by valance band electron tunneling during an erase operation, a defect density of one or both of the first semiconductor layer 33 or the second semiconductor layer 39 may be increased. That is, a defect density of one or both of the first semiconductor layer 33 or the second semiconductor layer 39 may be relatively high. In the defect state, energy levels may be formed in the band gap and a carrier may move through tunneling. Accordingly, a defect density of at least one of the first semiconductor layer 33 and the second semiconductor layer 39 may be increased by impurities or lattice defects and may provide a carrier movement path, such that conduction efficiency in forward current driven by major carrier conduction during an erase operation in a structure such as in FIG. 3A may be increased.

In the description below, an erase operation of a semiconductor device according to an example embodiment will be described with reference to FIGS. 4 and 9B. FIG. 9B is an energy band diagram illustrating an erase operation of the semiconductor device in FIG. 4.

Referring to FIGS. 4 and 9B, for an erase operation, a first erase voltage may be applied to the bit line (BL in FIG. 1), a second erase voltage may be applied to the common source structure 206, and a third erase voltage may be applied to the fourth upper gate electrode GU4, which may be an erase control gate electrode. Here, the contact plug 363 may be in contact with the first semiconductor layer 33 and the second semiconductor layer 39, and since the first erase voltage is a positive voltage, a field may not occur in the second semiconductor layer 39 during the erase operation.

Trap density may be high at an interfacial surface between the first semiconductor layer 33 and the second semiconductor layer 39, and the energy difference between the edge of the N-type conduction band and the edge of the valence band may be small, such that an energy barrier of the interfacial surface may be relatively low.

During an erase operation, even when a field is not generated in the second semiconductor layer 39, a conduction path in which hole tunneling and carrier generation are combined may be formed in vicinity of the interfacial surface between the first semiconductor layer 33 and the second semiconductor layer 39 as described above. Accordingly, holes generated in vicinity of the interfacial surface between the first semiconductor layer 33 and the second semiconductor layer 39 may migrate into the first semiconductor layer 33.

A read operation of a semiconductor device according to an example embodiment will be described with reference to FIGS. 3A and 9C. FIG. 9C is an energy band diagram illustrating a read operation of the semiconductor device in FIG. 3A.

Referring to FIGS. 3A and 9C, as described above with reference to FIG. 3A and FIG. 9A, a band offset between the first semiconductor layer 33 and the second semiconductor layer 39 may be relatively small, and a defect density of one or both of the first semiconductor layer 33 or the second semiconductor layer 39 may be relatively high. For example, since the band offset between the first semiconductor layer 33 and the second semiconductor layer 39 is small, charge carriers may easily move, and since the defect density of the second semiconductor layer 39 is high, traps helping the charge carriers to move may be activated. Accordingly, electrons in the first semiconductor layer 33 and the second semiconductor layer 39 may easily move to the conductive pad pattern 42. That is, since sufficient cell current may be assured during a read operation, data stored in the memory cell may be read accurately and reliably.

A read operation of a semiconductor device according to an example embodiment will be described with reference to FIGS. 4 and 9D. FIG. 9D is an energy band diagram illustrating a read operation of the semiconductor device in FIG. 4.

Referring to FIGS. 4 and 9D, as described above with reference to FIGS. 4 and 9B, the first and second semiconductor layers 33 and 39 may be in contact with the contact plug 363. Accordingly, during a read operation, since electrons in the first semiconductor layer 33 do not move into the second semiconductor layer 39 and may move directly to the contact plug 363, sufficient cell current may be assured, and data stored in the memory cell may be read more accurately and more reliably.

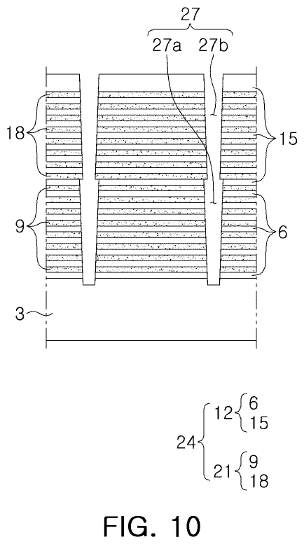

In the description below, an example of a method of forming a semiconductor device according to an example embodiment will be described with reference to FIGS. 10 to 13. FIGS. 10 to 13 are cross-sectional diagrams illustrating an example of a method of forming a semiconductor device according to an example embodiment.

Referring to FIG. 10, a mold structure 24 and a channel hole 27 penetrating the mold structure 24 may be formed on a substrate 3. The mold structure 24 may include a first mold structure 12 and a second mold structure 21 on the first mold structure 12. The first mold structure 12 may include first interlayer insulating layers 6 and first mold layers 9 alternately and repeatedly stacked, and the second mold structure 21 may include second interlayer insulating layers 15 and second mold layers 18 alternately and repeatedly stacked. The channel hole 27 may include a lower channel hole 27a penetrating the first mold structure 12 and an upper channel hole 27b penetrating the second mold structure 21.

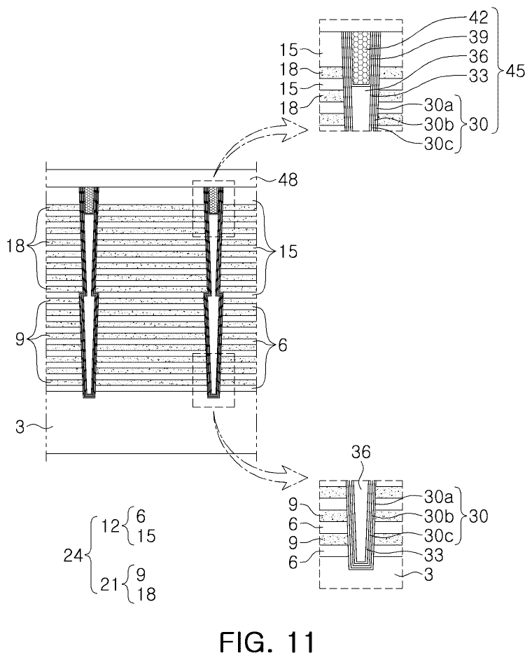

Referring to FIG. 11, a vertical structure 45 may be formed in the channel hole 27. The forming the vertical structure 45 may include forming a dielectric structure 30 conformally covering an internal wall of the channel hole 27, forming a first semiconductor layer 33 conformally covering the dielectric structure 30, forming an insulating core pattern 36 on the first semiconductor layer 33 partially filling the channel hole 27, forming a second semiconductor layer 39 conformally covering the channel hole 27 on the insulating core pattern 36, and forming a conductive pad pattern 42 on the second semiconductor layer 39 filling the other portion of the channel hole 27. The forming the dielectric structure 30 may include forming a first dielectric layer 30a, a data storage layer 30b, and a second dielectric layer 30c in order. A first insulating layer 48 may be formed on the mold structure 24 and the vertical structure 45.

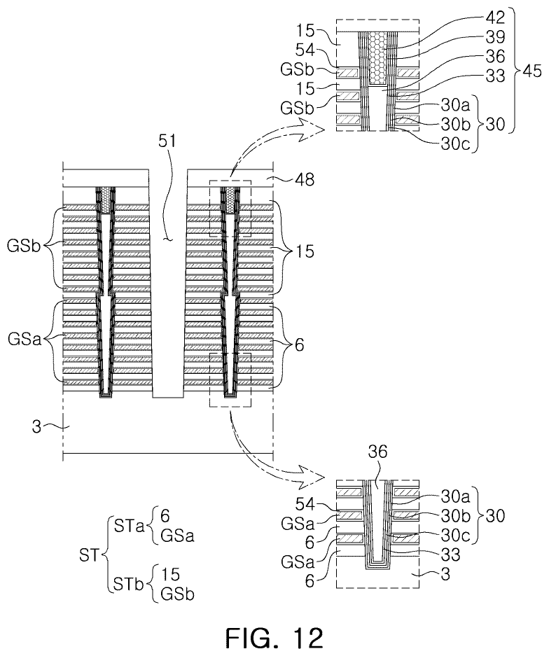

Referring to FIG. 12, an isolation trench 51 penetrating the first insulating layer 48 and the mold structure 24 may be formed and the first and second mold layers (9 and 18 in FIG. 11) of the mold structure 24 may be exposed. Void spaces may be formed by removing the first and second mold layers (9 and 18 in FIG. 11) exposed by the isolation trench 51, and the dielectric layers 54 and the conductive layers GSa and GSb, as described in FIG. 2, may be formed in the void spaces. The conductive layers GSa and GSb may include first conductive layers GSa formed in the void spaces from which the first mold layers (9 in FIG. 11) are removed, and second conductive layers GSb formed in the void spaces from which the second mold layers (18 in FIG. 11) are removed.

The first interlayer insulating layers 6 and the first conductive layers GSa may form the first stack structure STa, and the second interlayer insulating layers 15 and the second conductive layers GSb may form the second stack structure STb. The first stack structure STa and the second stack structure STb may form the stack structure ST.

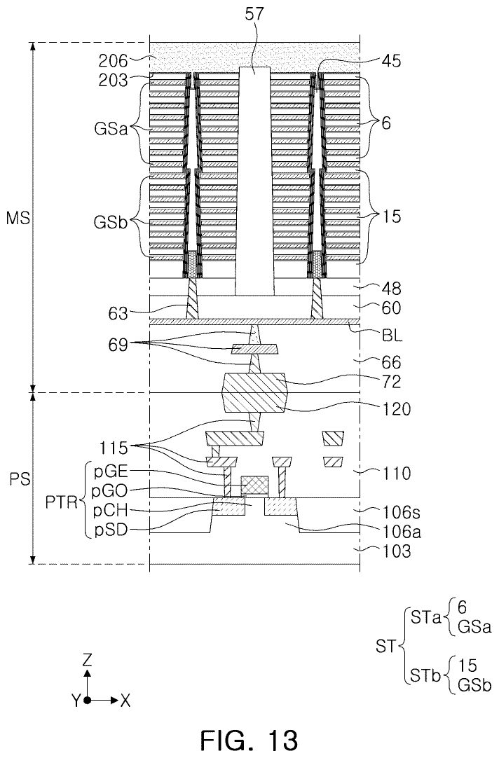

Referring to FIG. 13, an isolation structure 57 filling the isolation trench 51 may be formed. Thereafter, the insulating layer 60, the contact plug 63, the bit line BL, the insulating structure 66, the interconnection structure 69 and the first bonding pad 72 described in FIG. 1 may be formed. The peripheral structure PS described in FIG. 1 may be formed. By performing a wafer bonding process, the second bonding pad 120 of the peripheral structure PS and the first bonding pad 72 may be bonded to each other.

By removing the substrate (3 in FIG. 12), the dielectric structure (30 in FIG. 12) of the stack structure ST and the vertical structure 45 may be exposed. Thereafter, the exposed dielectric structure (30 in FIG. 12) and the first semiconductor layer (33 in FIG. 12) of the vertical structure 45 may be etched and the insulating core pattern 36 may be exposed, and a portion of the insulating core pattern 36 may be etched. Accordingly, the vertical structure 45 as in FIG. 2 may be formed.

Thereafter, the third semiconductor layer 203 and the source structure 206 may be formed in order. The third semiconductor layer 203 may be in contact with the first semiconductor layer 33 and may conformally cover the stack structure ST, and the source structure 206 may be formed on the third semiconductor layer 203.

Referring back to FIG. 1, an insulating layer 209 may be formed on the source structure 206, a conductive via 212 penetrating the insulating layer 209 and electrically connected to the source structure 206 may be formed, a source interconnection 215 electrically connected to the conductive via 212 may be formed, and an insulating layer 218 covering the source interconnection 215 may be formed. Accordingly, a memory structure MS vertically overlapping the peripheral structure PS may be formed.

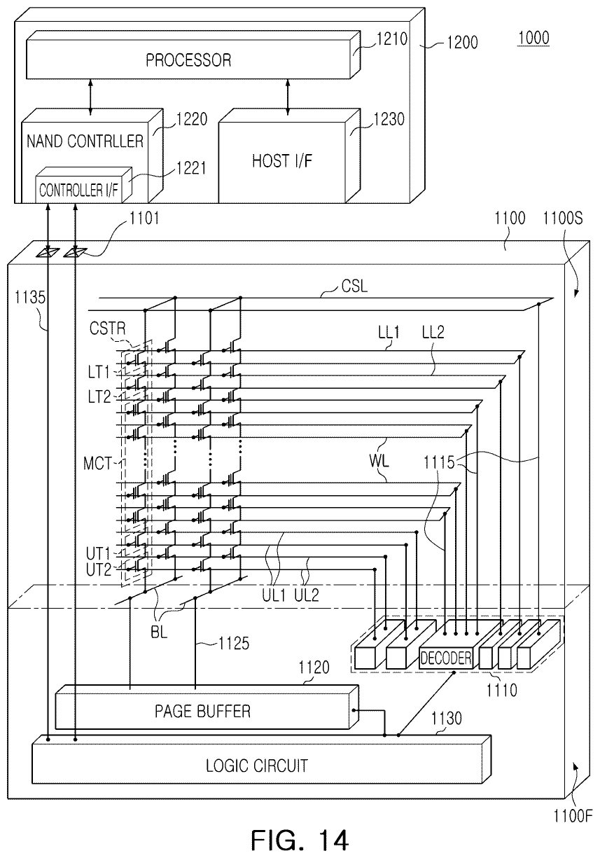

In the description below, a data storage system including a semiconductor device according to an example embodiment will be described with reference to FIG. 14. FIG. 14 is a diagram illustrating a data storage system including a semiconductor device according to an example embodiment.

Referring to FIG. 14, a data storage system 1000 according to an example embodiment may include a semiconductor device 1100 and a controller 1200 electrically connected to the semiconductor device 1100.

The data storage system 1000 may be configured as a storage device including one or a plurality of semiconductor devices 1100 or an electronic device including a storage device. For example, the data storage system 1000 may be implemented as a solid state drive device (SSD), a universal serial bus (USB), a computing system, a medical device, or a communication device including one or a plurality of semiconductor devices 1100.

The semiconductor device 1100 may be implemented as a non-volatile memory device, and may be, for example, a semiconductor device according to one of the example embodiments described with reference to FIGS. 1 to 10. The semiconductor device 1100 may include a first structure 110F and a second structure 1100S on the first structure 110F.

The first structure 1100F may be the peripheral structure PS in one of the example embodiments described in FIGS. 1 to 13, and the second structure 1100S may be the memory structure MS in one of the example embodiments described in FIGS. 1 to 13. The first structure 110F may include a decoder circuit 1110, a page buffer 1120, and a logic circuit 1130.

The second structure 1100S may include a bit line BL, a common source CSL, word lines WL, first and second gate upper lines UL1 and UL2, first and second gate lower lines LL1 and LL2, and memory cell strings CSTR between the bit line BL and the common source CSL.

The bit line BL described in FIG. 1 may be the bit lines BL.

The source structure 206 described in FIG. 1 may be the common source CSL.

The plurality of lower gate electrodes GL described in FIG. 1 and FIG. 2 may include the first and second gate lower lines LL1 and LL2.

The plurality of intermediate gate electrodes GMa and GMb described in FIG. 1 and FIG. 2 may include the word lines WL.

The plurality of upper gate electrodes GU described in FIGS. 1 and 2 may include the first and second gate upper lines UL1 and UL2.

In the second structure 1100S, each of the memory cell strings CSTR may include lower transistors LT1 and LT2 adjacent to the common source CSL, upper transistors UT1 and UT2 adjacent to the bit line BL, and a plurality of memory cell transistors MCT disposed between the lower transistors LT1 and LT2 and the upper transistors UT1 and UT2.

The number of the lower transistors LT1 and LT2 and the number of the upper transistors UT1 and UT2 may be varied according to example embodiments. The plurality of memory cell transistors MCT may include data storage regions for storing data.

The upper transistors UT1 and UT2 may include an upper erase control transistor and a string select transistor, and the lower transistors LT1 and LT2 may include a lower erase control transistor and a ground select transistor.

The gate lower lines LL1 and LL2 may be gate electrodes of lower transistors LT1 and LT2, respectively. The word lines WL may be gate electrodes of the memory cell transistors MCT, and the gate upper lines UL1 and UL2 may be gate electrodes of upper transistors UT1 and UT2, respectively.

The lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series.

At least one of the lower erase control transistors LT1 and the upper erase control transistor UT1 may be used for an erase operation of erasing data stored in the memory cell transistors MCT.

The common source CSL, the first and second gate lower lines LL1 and LL2, the word lines WL, and the first and second gate upper lines UL1 and UL2 may be electrically connected to the decoder circuit 1110 through first interconnections 1115 extending from the first structure 110F to the second structure 1100S. The bit lines BL may be electrically connected to the page buffer 1120 through second interconnections 1125 extending from the first structure 110F to the second structure 1100S.

In the first structure 110F, the decoder circuit 1110 and the page buffer 1120 may perform a control operation for at least one select memory cell transistor among the plurality of memory cell transistors MCT. The decoder circuit 1110 and the page buffer 1120 may be controlled by the logic circuit 1130.

The semiconductor device 1100 may communicate with the controller 1200 through an input/output pad 1101 electrically connected to the logic circuit 1130. The input/output pad 1101 may be electrically connected to the logic circuit 1130 through an input/output interconnection 1135 extending from in the first structure 110F to the second structure 1100S.

The controller 1200 may be configured to be electrically connected to the semiconductor device 1100 through the input/output pad 1101 and to control the semiconductor device 1100. The controller 1200 may include a processor 1210, a NAND controller 1220, and a host interface 1230. According to example embodiments, the data storage system 1000 may include a plurality of semiconductor devices 1100, and in this case, the controller 1200 may control the plurality of semiconductor devices 1000.

The processor 1210 may control overall operations of the data storage system 1000, including the controller 1200. The processor 1210 may operate according to predetermined firmware and may control the NAND controller 1220 and may access the semiconductor device 1100. The NAND controller 1220 may include a NAND interface 1221 handling communication with the semiconductor device 1100. A control command for controlling the semiconductor device 1100, data to be written to memory cell transistors MCT of the semiconductor device 1100, data to be read from memory cell transistors MCT of the semiconductor device 1100, or the like, may be transmitted through the NAND interface 1221. The host interface 1230 may provide a communication function between the data storage system 1000 and an external host. When a control command is received from an external host through the host interface 1230, the processor 1210 may control the semiconductor device 1100 in response to the control command.

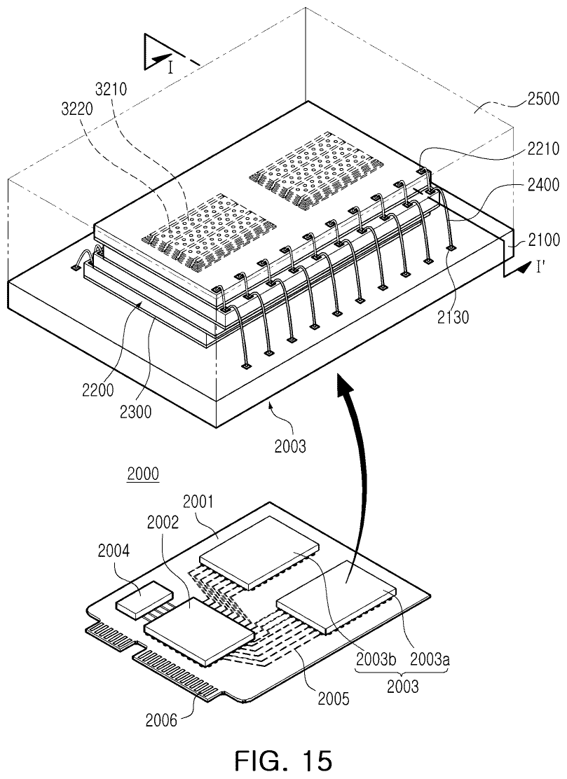

A data storage system including a semiconductor device according to an example embodiment will be described with reference to FIG. 15. FIG. 15 is a perspective diagram illustrating a data storage system including a semiconductor device according to an example embodiment.

Referring to FIG. 15, a data storage system 2000 according to an example embodiment may include a main board 2001, a controller 2002 mounted on the main board 2001, one or more semiconductor packages 2003, and a DRAM 2004. The semiconductor packages 2003 and the DRAM 2004 may be interconnected with the controller 2002 by interconnection patterns 2005 formed on the main board 2001.

The main board 2001 may include a connector 2006 including a plurality of pins coupled to an external host. The number of a plurality of pins in the connector 2006 and arrangement thereof may be varied depending on a communication interface between the data storage system 2000 and the external host. In example embodiments, the data storage system 2000 may communicate with the external host according to one of interfaces such as universal serial bus (USB), peripheral component interconnect express (PCI-Express), serial advanced technology attachment (SATA), M-Phy for universal flash storage (UFS), or the like. In example embodiments, the data storage system 2000 may operate by power supplied from the external host through the connector 2006. The data storage system 2000 may further include a power management integrated circuit (PMIC) distributing power supplied from the external host to the controller 2002 and the semiconductor package 2003.

The controller 2002 may write data to the semiconductor package 2003 or may read data from the semiconductor package 2003, and may improve the operation speed of the data storage system 2000.

The DRAM 2004 may be a buffer memory to alleviate the speed difference between the semiconductor package 2003, which is a data storage space, and an external host. The DRAM 2004 included in the data storage system 2000 may also operate as a cache memory, and may provide a space for temporarily storing data in a control operation for the semiconductor package 2003. When the DRAM 2004 is included in the data storage system 2000, the controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input/output pad 2210. The input/output pad 2210 may correspond to the input/output pad 1101 in FIG. 14.

Each of the semiconductor chips 2200 may include stack structures 3210 and memory vertical structures 3220. Each of the semiconductor chips 2200 may include a semiconductor device 1 in one of the example embodiments described in FIGS. 1 to 13.

The stack structures 3210 may be a stack structure ST in one of the example embodiments described in FIGS. 1 to 13. The memory vertical structures 3220 may be vertical structures 45 in one of the example embodiments described in FIGS. 1 to 13.

The connection structure 2400 may be a bonding wire electrically connecting the input/output pads 2210 to the package upper pads 2130. Accordingly, in each of the first and second semiconductor packages 2003a and 2003b, the semiconductor chips 2200 may be electrically connected to each other by a bonding wire method and may be electrically connected to the package upper pads 2130 of the package substrate 2100. In example embodiments, in each of the first and second semiconductor packages 2003a and 2003b, the semiconductor chips 2200 may be electrically connected to each other by a connection structure including a through-electrode (through silicon via, TSV), instead of a bonding wire method connection structure 2400.

In example embodiments, the controller 2002 and the semiconductor chips 2200 may be included in a single package. In an example embodiment, the controller 2002 and the semiconductor chips 2200 may be mounted on another interposer substrate different from the main board 2001, and the controller 2002 and the semiconductor chips 2200 may be connected to each other by interconnection formed on the interposer substrate.

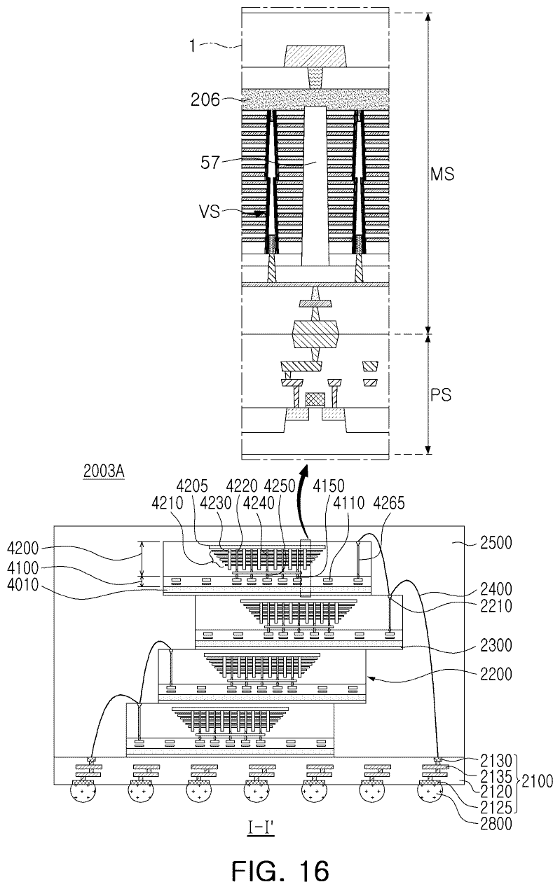

FIG. 16 is a cross-sectional diagram illustrating semiconductor packages according to an example embodiment. FIG. 16 illustrates an example embodiment of the semiconductor package 2003 in FIG. 15, and illustrates a region taken along line I-I′ of the semiconductor package 2003 in FIG. 15.

Referring to FIGS. 15 and 16, in the semiconductor package 2003A, each of the semiconductor chips 2200a may include a substrate 4010, a first structure 4100 on the substrate 4010, and a second structure 4200 bonded to the first structure 4100 by a wafer bonding manner on the first structure 4100.

Each of the semiconductor chips 2200a may include a semiconductor device 1 in one of the example embodiments described in FIGS. 1 to 13.

The first structure 4100 may be the peripheral structure PS in one of the example embodiments described in FIGS. 1 to 13 and/or the first structure 1100F described in FIG. 14, and the second structure 1100S may be the memory structure MS in one of the example embodiments described in FIGS. 1 to 13 and/or the second structure 1100S described in FIG. 14.

The first structure 4100 may include a peripheral circuit region including a peripheral interconnection 4110 and first bonding structures 4150.

The first bonding structures 4150 may be the second bonding pad 120 of the peripheral structure PS in FIG. 1, and the peripheral interconnection 4110 may be the peripheral interconnection structure 115 of the peripheral structure PS in FIG. 1.

The second structure 4200 may include a common source 4205, a stack structure 4210 between the common source 4205 and the first structure 4100, memory vertical structures 4220, isolation structures 4230 penetrating the stack structure 4210, and second bonding structures 4250 electrically connected to the word lines (WL in FIG. 14) of the memory vertical structures 4220 and the stack structure 4210, respectively. For example, the second bonding structures 4250 may be electrically connected to the memory vertical structures 4220 and the word lines (WL in FIG. 14) through gate interconnections electrically connected to the bit lines 4240 and the word lines (WL in FIG. 14) electrically connected to the memory vertical structures 4220, respectively.

The second bonding structures 4250 may be the first bonding pad 72 of the memory structure MS in FIG. 1, the stack structure 4210 may be the stack structure ST in FIGS. 1 and 2, the memory vertical structures 4220 may be the vertical structure 45 in FIGS. 1 and 2, the common source 4205 may be the source structure 206 in FIGS. 1 and 2, and the isolation structures 4230 may be the isolation structure 57 in FIG. 1. The first bonding structures 4150 of the first structure 4100 and the second bonding structures 4250 of the second structure 4200 may be in contact with and bonded to each other. Each of the semiconductor chips 2200a may further include an input/output pad 2210. The semiconductor chips 2200a may be electrically connected to each other by connection structures 2400 in the form of bonding wires. However, in example embodiments, the semiconductor chips in a single semiconductor package, such as the semiconductor chips 2200a, may also be electrically connected to each other by a connection structure including a through-electrode (TSV).

In example embodiments, an erase operation for erasing data stored in the memory cell transistors (MCT in FIG. 14) may include electrons trapped in the data storage layer (30b in FIG. 2) of the memory cell transistors (MCT in FIG. 14) escaping into the first semiconductor layer (33 in FIG. 2) of the memory cell transistors MCT by the F-N tunneling phenomenon. Here, the first semiconductor layer (33 in FIG. 2) may be used as a channel of the memory cell transistors (MCT in FIG. 14).

In the erase operation, a hole generated by the GIDL (gate induced drain leakage) phenomenon in the lower and upper erase transistors (LT1 and UT2 in FIG. 14), and as described in FIGS. 9A and 9B, a hole may move from the interfacial surface between the first semiconductor layer 33 and the second semiconductor layer 39 into the first semiconductor layer 33, the holes may be implanted into the channel of the memory cell transistors MCT, that is, the first semiconductor layer 33, and the data of the memory cell transistors MCT may be erased by the holes implanted into the channel of the memory cell transistors MCT. For example, the holes implanted into the channel of the memory cell transistors MCT, that is, the first semiconductor layer 33, may allow electrons trapped in the data storage layer 30b of the memory cell transistors MCT to escape through the channel of the memory cell transistors MCT. Accordingly, the erasing efficiency of electrons trapped in the data storage layer (30b in FIG. 2) of the memory cell transistors (MCT in FIG. 14) escaping into the first semiconductor layer (33 in FIG. 2) of the memory cell transistors MCT may be increased.

According to the aforementioned example embodiments, a stack structure including gate electrodes stacked in a vertical direction and a vertical structure penetrating the stack structure and including a data storage layer may be provided, such that integration density of the semiconductor device may be improved.

Also, a region of the vertical structure facing the erase control gate electrode may include different first semiconductor layers and second semiconductor layers so as to increase erase efficiency during an erase operation.

Accordingly, a semiconductor device which may improve integration density and may increase erase efficiency during an erase operation may be provided.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While example embodiments have been illustrated and described above, it will be apparent to those skilled in the art that modifications and variations could be made without departing from the scope of the present disclosure as defined by the appended claims.

What is claimed is:

1. A semiconductor device, comprising:
a peripheral structure including a peripheral circuit; and
a memory structure vertically overlapping the peripheral structure,
wherein the memory structure includes a stack structure, a vertical structure, and a contact plug on the vertical structure,
the stack structure includes interlayer insulating layers and conductive layers alternately stacked in a vertical direction,
the vertical structure is in a channel hole penetrating the stack structure,
wherein the conductive layers include a plurality of lower gate electrodes, a plurality of intermediate gate electrodes on the plurality of lower gate electrodes, and a plurality of upper gate electrodes on the plurality of intermediate gate electrodes,
wherein the vertical structure includes
a dielectric structure covering a sidewall of the channel hole and including a data storage layer,
a first semiconductor layer covering an internal side surface of the dielectric structure,
a conductive pad pattern connected to the contact plug,
an insulating core pattern below the conductive pad pattern, and
a second semiconductor layer between the first semiconductor layer and the conductive pad pattern,
wherein a first portion of the first semiconductor layer is between the conductive pad pattern and the dielectric structure, and a second portion of the first semiconductor layer is between the insulating core pattern and the dielectric structure,
wherein a lower end of the second semiconductor layer is at a higher level than the plurality of intermediate gate electrodes and at a lower level than a first upper erase control gate electrode among the plurality of upper gate electrodes,
wherein an upper end of the second semiconductor layer is at a higher level than the first upper erase control gate electrode,
wherein the first semiconductor layer includes a first oxide semiconductor having N-type conductivity, and
wherein the second semiconductor layer includes at least one of a second oxide semiconductor, a silicon (Si) semiconductor, a germanium (Ge) semiconductor, or a silicon germanium (SiGe) semiconductor.

2. The semiconductor device of claim 1,
wherein the second semiconductor layer includes the second oxide semiconductor, and
wherein the second oxide semiconductor has P-type conductivity.

3. The semiconductor device of claim 1,
wherein the second semiconductor layer includes at least one of the silicon (Si) semiconductor, the germanium (Ge) semiconductor, or the silicon germanium (SiGe) semiconductor, and
wherein the silicon (Si) semiconductor, the germanium (Ge) semiconductor, and the silicon germanium (SiGe) semiconductor have P-type conductivity.

4. The semiconductor device of claim 1, wherein the second semiconductor layer extends from a region between the conductive pad pattern and the first semiconductor layer to a region between a lower surface of the conductive pad pattern and an upper surface of the insulating core pattern.

5. The semiconductor device of claim 4,
wherein the plurality of lower gate electrodes include a first lower erase control gate electrode, and
wherein a lower surface of the insulating core pattern is at a higher level than the first lower erase control gate electrode.

6. The semiconductor device of claim 5,
wherein the memory structure includes
a source structure disposed below the stack structure,
a protruding conductive pattern extending from the source structure into the channel hole, and
a third semiconductor layer between the protruding conductive pattern and the first semiconductor layer,
wherein an upper end of the third semiconductor layer is at a lower level than the plurality of intermediate gate electrodes and at a higher level than the first lower erase control gate electrode, and
wherein the third semiconductor layer includes at least one of a third oxide semiconductor, a silicon (Si) semiconductor, a germanium (Ge) semiconductor, or a silicon germanium (SiGe) semiconductor.

7. The semiconductor device of claim 6, wherein
the third semiconductor layer extends between the protruding conductive pattern and the first semiconductor layer to a region between an upper surface of the protruding conductive pattern and a lower surface of the insulating core pattern.

8. The semiconductor device of claim 7, wherein
a first portion of the third semiconductor layer is between the protruding conductive pattern and the first semiconductor layer,
a second portion of the third semiconductor layer is between an upper surface of the source structure and a lower surface of the stack structure, and
the first portion of the third semiconductor layer extends to the second portion of the third semiconductor layer.

9. The semiconductor device of claim 6, wherein
the plurality of lower gate electrodes further include a second lower erase control gate electrode at a higher level than the first lower erase control gate electrode, and
the upper end of the third semiconductor layer is at a higher level than the second lower erase control gate electrode.

10. The semiconductor device of claim 1,
wherein the plurality of upper gate electrodes further includes a second upper erase control gate electrode at a lower level than the first upper erase control gate electrode, and
wherein the lower end of the second semiconductor layer is at a lower level than the second upper erase control gate electrode.

11. The semiconductor device of claim 1,
wherein the vertical structure further includes a metal layer between the first semiconductor layer and the second semiconductor layer, and
wherein a thickness of the metal layer is smaller than each of a thickness of the first semiconductor layer and a thickness of the second semiconductor layer.

12. The semiconductor device of claim 11,
wherein the second semiconductor layer includes the second oxide semiconductor, and
wherein the metal layer includes at least one of a first metal element of the first oxide semiconductor of the first semiconductor layer or a second metal element of the second oxide semiconductor of the second semiconductor layer.

13. The semiconductor device of claim 1,
wherein the memory structure further includes a source structure disposed below the stack structure,
wherein a lower surface of the insulating core pattern is at a lower level than the plurality of lower gate electrodes, and
wherein the first semiconductor layer extends from a portion disposed between the insulating core pattern and the dielectric structure to a region between the insulating core pattern and the source structure.

14. The semiconductor device of claim 1, wherein the contact plug is in contact with the conductive pad pattern, and the contact plug is spaced apart from the first semiconductor layer.

15. The semiconductor device of claim 1, wherein the contact plug is in contact with the conductive pad pattern, the second semiconductor layer, and the first semiconductor layer.

16. A semiconductor device, comprising:
a stack structure including interlayer insulating layers and conductive layers alternately stacked in a vertical direction;
a vertical structure in a channel hole penetrating the stack structure; and
a contact plug connected to the vertical structure and on the vertical structure,
wherein the conductive layers include
a plurality of lower gate electrodes,
a plurality of intermediate gate electrodes on the plurality of lower gate electrodes, and
a plurality of upper gate electrodes on the plurality of intermediate gate electrodes,
wherein the vertical structure includes
a first semiconductor layer facing the plurality of lower gate electrodes, the plurality of intermediate gate electrodes, and the plurality of upper gate electrodes,
a second semiconductor layer at a higher level than the plurality of intermediate gate electrodes and facing at least one erase control gate electrode among the plurality of upper gate electrodes, and
a conductive pad pattern spaced apart from the first semiconductor layer and in contact with the second semiconductor layer,
wherein the first semiconductor layer includes a first oxide semiconductor having a band gap larger than a band gap of a silicon semiconductor, and
wherein the second semiconductor layer includes at least one of a second oxide semiconductor, a silicon (Si) semiconductor, a germanium (Ge) semiconductor, or a silicon germanium (SiGe) semiconductor.

17. The semiconductor device of claim 16,
wherein the first oxide semiconductor has N-type conductivity,
wherein the second semiconductor layer includes the second oxide semiconductor, and
wherein the second oxide semiconductor has P-type conductivity.

18. The semiconductor device of claim 16,
wherein the conductive pad pattern does not include a doped semiconductor and the conductive pad pattern includes a metallic material,
wherein the plurality of upper gate electrodes further includes a string select gate electrode at a lower level than the at least one erase control gate electrode, and
wherein the second semiconductor layer is at a higher level than the string select gate electrode.

19. A data storage system, comprising:
a semiconductor device including an input/output pad; and
a controller electrically connected to the semiconductor device through the input/output pad, the controller being configured to control the semiconductor device,
wherein the semiconductor device includes
a peripheral structure including a peripheral circuit, and
a memory structure vertically overlapping the peripheral structure,
wherein the memory structure includes a stack structure, a vertical structure, and a contact plug on the vertical structure,
the stack structure includes interlayer insulating layers and conductive layers alternately stacked in a vertical direction, and
the vertical structure is in a channel hole penetrating the stack structure,
wherein the conductive layers include
a plurality of lower gate electrodes,
a plurality of intermediate gate electrodes on the plurality of lower gate electrodes, and
a plurality of upper gate electrodes on the plurality of intermediate gate electrodes,
wherein the vertical structure includes
a dielectric structure covering a sidewall of the channel hole and including a data storage layer,
a first semiconductor layer covering an internal side surface of the dielectric structure,
a conductive pad pattern connected to the contact plug,
an insulating core pattern below the conductive pad pattern, and
a second semiconductor layer between the first semiconductor layer and the conductive pad pattern,
wherein a first portion of the first semiconductor layer is between the conductive pad pattern and the dielectric structure, and a second portion of the first semiconductor layer is between the insulating core pattern and the dielectric structure,
wherein a lower end of the second semiconductor layer is at a higher level than the plurality of intermediate gate electrodes and at a lower level than a first upper erase control gate electrode among the plurality of upper gate electrodes,
wherein an upper end of the second semiconductor layer is at a higher level than the first upper erase control gate electrode,
wherein the first semiconductor layer includes a first oxide semiconductor having N-type conductivity, and
wherein the second semiconductor layer includes at least one of a second oxide semiconductor, a silicon (Si) semiconductor, a germanium (Ge) semiconductor, or a silicon germanium (SiGe) semiconductor.

20. The data storage system of claim 19,
wherein the second semiconductor layer includes the second oxide semiconductor, and
wherein the second oxide semiconductor has P-type conductivity.
